(19) United States
(12) Patent Application Publication
(10) Pub. No.: US 2026/0171146 A1
(43) Pub. Date: Jun. 18, 2026

(54) MEMORY DEVICE INCLUDING ASSIST CIRCUIT FOR ADJUSTING VOLTAGE LEVEL OF WORDLINE

(71) Applicant: SAMSUNG ELECTRONICS CO., LTD., Suwon-si (KR)

(72) Inventors: KIRYONG KIM, Suwon-si (KR); JEONSEUNG KANG, Suwon-si (KR)

(73) Assignee: SAMSUNG ELECTRONICS CO., LTD., Suwon-si (KR)

(21) Appl. No.: 19/290,873

(22) Filed: Aug. 5, 2025

(30) Foreign Application Priority Data
Dec. 18, 2024 (KR) 10-2024-0189362

(51) Int. Cl. G11C 11/418; G11C 11/419

(52) U.S. Cl. CPC G11C 11/418; G11C 11/419

(57) ABSTRACT

A memory device includes a memory cell array including memory cells, a row decoder that selects one of wordlines connected to the memory cells, based on an address received from a memory controller, and a wordline voltage generator that provides a wordline voltage to a selected wordline. The wordline voltage generator includes wordline drivers that respectively correspond to the wordlines, and wordline underdrive circuits that respectively correspond to the wordlines and that lower wordline voltage levels that are output by the wordline drivers by different voltage levels based on the address.

### CROSS-REFERENCE TO RELATED APPLICATION

This application claims priority under 35 U.S.C. § 119 to Korean Patent Application No. 10-2024-0189362 filed on Dec. 18, 2024, in the Korean Intellectual Property Office, the disclosure of which being incorporated by reference herein in its entirety.

### BACKGROUND

Example embodiments of the present disclosure described herein relate to a semiconductor memory device, and more particularly, relate to a memory device including an assist circuit for controlling a voltage level of a wordline.

A semiconductor memory may be mainly classified as a volatile memory or a non-volatile memory. Read and write speeds of the volatile memory (for example, a DRAM or an SRAM) are fast, but the data stored in the volatile memory disappear when a power is turned off. In contrast, the non-volatile memory may retain data even when the power is turned off.

As semiconductor process technology is refined, resistance of a metal layer continues to increase in memory cells of a static random access memory (SRAM). When resistance of bitlines of the SRAM increases, an error may occur in a read or write operation.

### SUMMARY

It is an aspect to provide a memory device including an assist circuit which differently controls a wordline voltage level supplied to each wordline during a read or write operation.

According to an aspect of one or more example embodiments, there is provided a memory device comprising a memory cell array including a plurality of memory cells; a row decoder configured to select one of a plurality of wordlines connected to the plurality of memory cells based on an address received from a memory controller; and a wordline voltage generator configured to provide a wordline voltage to a selected wordline. The wordline voltage generator comprises a plurality of wordline drivers that respectively correspond to the plurality of wordlines; and a plurality of wordline underdrive circuits that respectively correspond to the plurality of wordlines and that lower wordline voltage levels that are output by the plurality of wordline drivers by different voltage levels based on the address.

According to another aspect of one or more example embodiments, there is provided a memory device comprising a memory cell array including a first memory cell and a second memory cell; a row decoder configured to select one of a first wordline connected to the first memory cell and a second wordline connected to the second memory cell based on an address received from a memory controller; a first wordline driver configured to provide a wordline voltage to the first wordline when the first wordline is selected; a second wordline driver configured to provide the wordline voltage to the second wordline when the second wordline is selected; a first wordline underdrive circuit configured to reduce a voltage level of the first wordline by a first voltage level when the first wordline is selected; and a second wordline underdrive circuit configured to reduce a voltage level of the second wordline by a second voltage level when the second wordline is selected, the second voltage level being greater than the first voltage level.

According to yet another aspect of one or more example embodiments, there is provided a memory device comprising a memory cell array including a plurality of memory cells; a row decoder configured to select one of a plurality of wordlines connected to the plurality of memory cells based on an address received from a memory controller; and a wordline voltage generator configured to provide a wordline voltage level to a selected wordline that is different based on the address.

### BRIEF DESCRIPTION OF THE FIGURES

The above and other aspects will become apparent by describing in detail embodiments thereof with reference to the accompanying drawings, in which:

FIG. 1 is a block diagram illustrating a storage device according to an example embodiment;

FIG. 2 is a block diagram illustrating the memory device illustrated in FIG. 1, according to an example embodiment;

FIG. 3 is a circuit diagram illustrating a memory cell array of the memory device illustrated in FIG. 2, according to an example embodiment;

FIG. 4 is a diagram illustrating wordlines connected to memory cells of the memory cell array of FIG. 3 and wordline drivers connected to the wordlines according to an example embodiment;

FIG. 5 is a diagram illustrating a wordline voltage generator, according to an example embodiment;

FIG. 6 is a diagram illustrating an underdrive circuit of the wordline voltage generator of FIG. 5, according to an example embodiment;

FIG. 7 is a diagram illustrating an underdrive circuit of the wordline voltage generator of FIG. 5, according to an example embodiment;

FIG. 8 is a diagram illustrating an underdrive circuit of the wordline voltage generator of FIG. 5, according to an example embodiment;

FIG. 9 is a diagram illustrating an underdrive circuit of the wordline voltage generator of FIG. 5, according to an example embodiment;

FIG. 10 is a diagram illustrating a wordline voltage generator, according to an example embodiment; and

FIG. 11 is a diagram illustrating a layout of the wordline voltage generator of FIG. 10 according to an example embodiment.

### DETAILED DESCRIPTION

Below, various example embodiments will be described in detail and clearly to such an extent that an ordinary one in the art easily implements the various example embodiments.

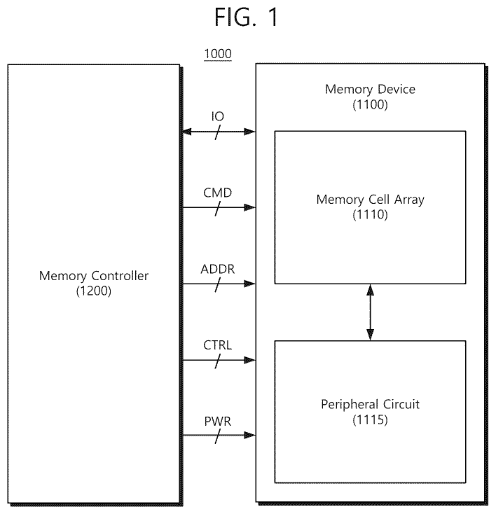

FIG. 1 is a block diagram illustrating a storage device according to an example embodiment. Referring to FIG. 1, a storage device 1000 may include a memory device 1100 and a memory controller 1200.

The memory device 1100 may receive input/output signals IO from the memory controller 1200 through input/output lines, receive control signals CTRL through control lines, and receive external supply power PWR through power lines. The memory device 1100 may receive commands CMD and addresses ADDR from the memory controller 1200. The storage device 1000 may store data in the memory device 1100 under control of the memory controller 1200.

The memory device 1100 may include a memory cell array 1110 and a peripheral circuit 1115. The memory cell array 1110 may have a planar 2D structure or a vertical 3D structure. The memory cell array 1110 may include a plurality of memory cells. The memory cell array 1110 may be positioned beside or over the peripheral circuit 1115.

The peripheral circuit 1115 may include analog circuits and/or digital circuits used to store data in the memory cell array 1110 or read data stored in the memory cell array 1110. The peripheral circuit 1115 may receive the external supply power PWR through the power lines and generate internal powers of various levels based on the external supply power PWR.

The peripheral circuit 1115 may receive data from the memory controller 1200 through the input/output lines. The peripheral circuit 1115 may store data in the memory cell array 1110 according to the control signals CTRL. Alternatively or additionally, the peripheral circuit 1115 may read data stored in the memory cell array 1110 and provide the read data to the memory controller 1200.

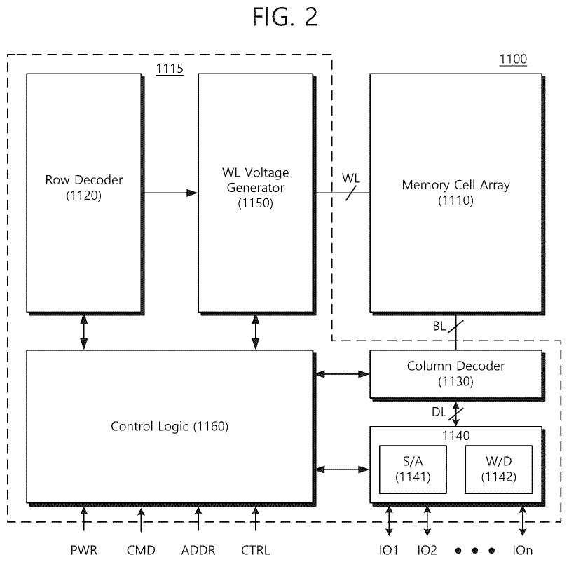

FIG. 2 is a block diagram illustrating the memory device 1100 of the storage device 1000 illustrated in FIG. 1, according to an example embodiment. Referring to FIG. 2, the memory device 1100 may include the memory cell array 1110 and the peripheral circuit 1115. The peripheral circuit 1115 may include a row decoder 1120, a column decoder 1130, an input/output circuit 1140, a wordline (WL) voltage generator 1150 and/or control logic 1160.

The memory cell array 1110 may be connected to a plurality of wordlines WL. The memory cell array 1110 may be connected to a wordline voltage generator 1150 through the plurality of wordlines WL.

The row decoder 1120 may select a wordline during a write or read operation. The row decoder 1120 may select the wordline based on a row address included in an address ADDR.

The column decoder 1130 may be connected to the memory cell array 1110 through a plurality of bitlines BL. The column decoder 1130 may select one or more bitlines based on a column address included in the address ADDR.

The input/output circuit 1140 may be internally connected to the column decoder 1130 through data lines DL and externally connected to the memory controller 1200 (refer to FIG. 1) through input/output lines IO1 to IOn. The input/output circuit 1140 may receive write data from the memory controller 1200 during a write operation.

The input/output circuit 1140 may provide data read from the memory cell array 1110 to the memory controller 1200 during a read operation. The input/output circuit 1140 may output the data through the input/output lines IO1 to IOn. The number of input/output lines IO1 to IOn may be determined based on a kind of the storage device 1000.

The input/output circuit 1140 may include a plurality of sense amplifiers S/A 1141 and a plurality of write drivers W/D 1142. The plurality of sense amplifiers S/A 1141 may read data from memory cells connected to a selected wordline during a read operation. The plurality of write drivers W/D 1142 may store data to memory cells connected to a selected wordline during a write operation.

The wordline (WL) voltage generator 1150 may receive internal power from the control logic 1160 and generate a wordline voltage used to read or write data. The wordline voltage may be provided to a selected wordline based on an address from the row decoder 1120.

The control logic 1160 may control operations such as read and/or write of the memory device 1100 using commands CMD, addresses ADDR and control signals CTRL provided from the memory controller 1200. The addresses ADDR may include a row address for selecting one wordline and a column address for selecting one memory cell.

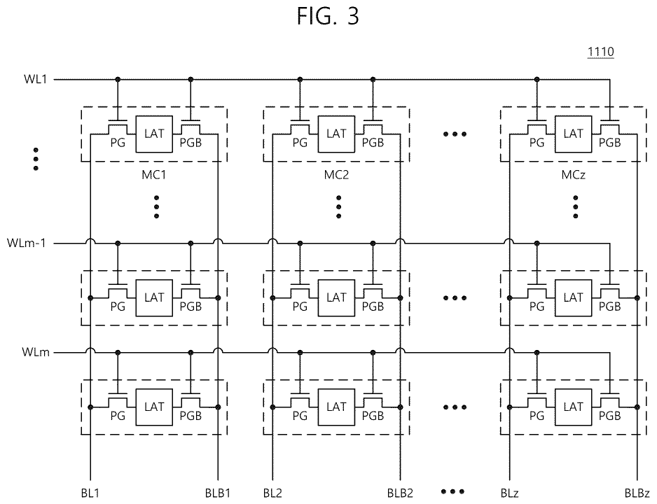

FIG. 3 is a circuit diagram illustrating the memory cell array 1110 of the memory device 1100 illustrated in FIG. 2, according to an example embodiment. Referring to FIG. 3, the memory cell array 1110 may include a plurality of memory cells (for example, MC1 to MCz). In an example embodiment, each memory cell may be a static random access memory cell.

The memory cell array 1110 may be connected to the row decoder 1120 and/or the wordline voltage generator 1150 through first to mth wordlines WL1 to WLm. The memory cell array 1110 may be connected to the column decoder 1130 through first to zth bitlines (BL1 to BLz, BLB1 to BLBz). As an example, BLB1 to BLBz may have complementary voltage levels with BL1 to BLz. For example, in some example embodiments, when BL1 is at a high level, BLB1 may be at a low level.

Each memory cell of the memory cell array 1110 may include a latch circuit LAT including inverters and pass gates PG and PGB. For example, the first memory cell MC1 may be connected to the first wordline WL1 and the first bitlines BL1 and BLB1. The first wordline WL1 may be connected to gates of a first pass gate PG and a second pass gate PGB. The first bitlines BL1 and BLB1 may be connected to drains or sources of the first and second pass gates PG and PGB.

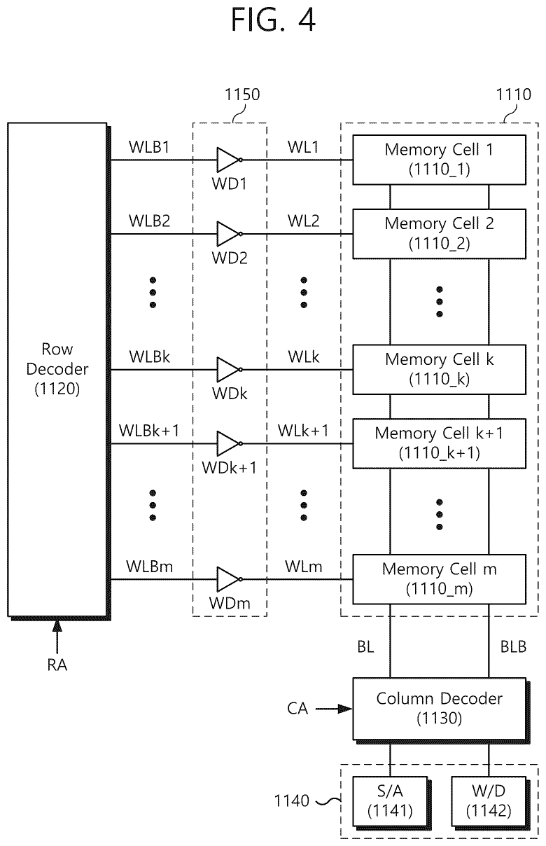

FIG. 4 is a diagram illustrating wordlines connected to the memory cells of the memory cell array 1110 of FIG. 3, according to an example embodiment, and wordline drivers WD connected to the wordlines WL according to an example embodiment. Referring to FIGS. 2 and 4, the memory cell array 1110 may include a plurality of memory cells 1110_1 to 1110_m. As an example, the plurality of memory cells 1110_1 to 1110_m are memory cells connected to one bitline BL. The memory cell 1110_1 is a memory cell located farthest from the column decoder 1130 or the input/output circuit 1140. The memory cell 1110_m is a memory cell located closest to a column decoder 1130 or an input/output circuit 1140. The memory cell 1110_k is a memory cell located between the memory cell 1110_1 and the memory cell 1110_m.

The plurality of memory cells 1110_1 to 1110_m may be connected to a plurality of wordlines WL1 to WLm, respectively. Each of the plurality of wordlines WL1 to WLm may transmit wordline voltages to pass gates (e.g., PG or PGB in FIG. 3) of the memory cell that is connected to the corresponding wordline.

The wordline voltage generator 1150 may include a plurality of wordline drivers WD1 to WDm. Output terminals of the plurality of wordline drivers WD1 to WDm may be connected to the plurality of wordlines WL1 to WLm, respectively. Input terminals of the plurality of wordline drivers WD1 to WDm may be connected to a plurality of complementary wordlines WLB1 to WLBm, respectively.

The row decoder 1120 may select a wordline based on a row address RA included in the address ADDR of FIG. 2. For example, the row decoder 1120 may provide a wordline drive signal to one of the plurality of complementary wordlines WLB1 to WLBm selected based on the row address RA. The wordline driver connected to a selected complementary wordline may invert the wordline drive signal based on the power supply voltage and output an inverted wordline drive signal to the selected wordline.

The column decoder 1130 may select one or more bitlines based on a column address CA included in the address ADDR of FIG. 2. During a write operation, the write driver W/D 1142 corresponding to the bitlines BL and BLB that are selected may transmit data to the bitlines BL and BLB that are selected. During a read operation, the sense amplifier S/A 1141 corresponding to the bitlines that are selected BL and BLB may detect voltages of the bitlines BL and BLB that are selected.

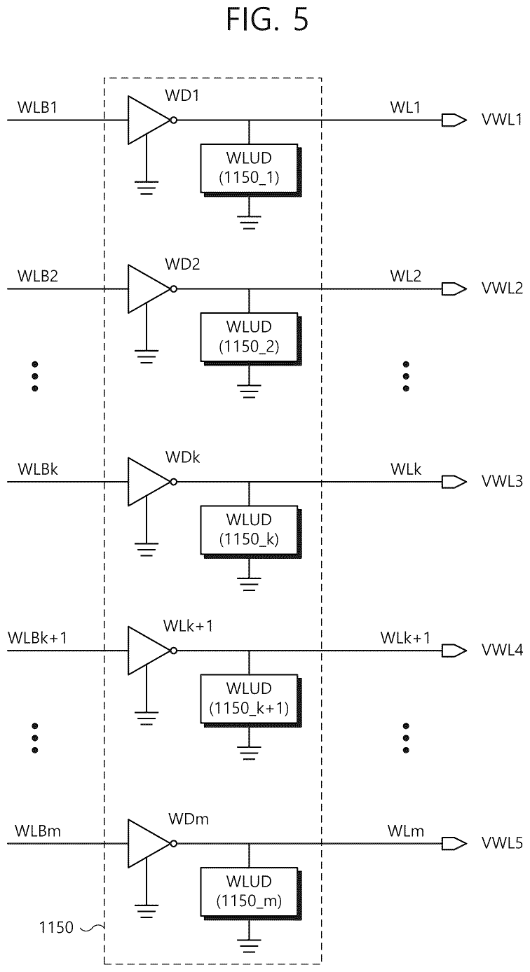

FIG. 5 is a diagram illustrating the wordline voltage generator 1150 of FIG. 4, according to an example embodiment. Referring to FIGS. 4 and 5, the wordline voltage generator 1150 may include an assist circuit to prevent a read disturbance. For example, the assist circuit may include wordline underdrive circuit (WLUD) 1150_1 to wordline underdrive circuit (WLUD) 1150_m. The wordline underdrive circuits 1150_1 to 1150_m may be respectively connected to the plurality of wordlines WL1 to WLm.

As a process is refined or an operating voltage is lowered, the read disturbance may occur in which writing is performed on a memory cell during a read operation or writing is performed on a memory cell that is not a writing target during a write operation. The wordline underdrive circuits 1150_1 to 1150_m may improve the read disturbance by lowering a voltage level of the selected wordline.

As a process is refined, a resistance of the bitline BL may increase. Accordingly, the disturbance margin of the memory cells, which is a probability that the read disturbance will not occur for each wordline, may have variable values. For example, the disturbance margin of a memory cell may increase as the distance from the memory cell to the column decoder 1130 or the input/output circuit 1140 increases. In other words, the disturbance margin of a memory cell that is farther from the column decoder 1130 or the input/output circuit 1140 may be higher than the disturbance margin of a memory cell that is closer to the column decoder 1130 or the input/output circuit 1140.

The read disturbance may be improved by lowering the wordline voltage level through the wordline underdrive circuits 1150_1 to 1150_m. However, as disturbance margins may be different for each of the wordlines, when the wordline voltage levels of all wordlines are lowered equally, an unnecessary drop of a wordline voltage may occur depending on a position of a wordline.

In an example embodiment, the wordline underdrive circuits 1150_1 to 1150_m may perform a wordline underdrive operation based on a disturbance margin of a selected wordline. For example, the wordline underdrive circuits 1150_1 to 1150_m may perform different wordline underdrive operations based on a row address RA of a wordline selected among the plurality of wordlines WL1 to WLm.

According to an example embodiment, the wordline underdrive circuits 1150_1 to 1150_m may sequentially increase a width of voltage drop of a selected wordline according to a distance from the selected wordline to the column decoder 1130 or the input/output circuit 1140. For example, in an example embodiment, the wordline underdrive circuit 1150_1 may have a greatest resistance. The wordline underdrive circuit 1150_2 may have a smaller resistance than the wordline underdrive circuit 1150_1. The wordline underdrive circuit 1150_k may have a smaller resistance than the wordline underdrive circuit 1150_2. The wordline underdrive circuit 1150_k+1 may have a smaller resistance than the wordline underdrive circuit 1150_k. The wordline underdrive circuit 1150_m may have a smaller resistance than the wordline underdrive circuit 1150_k+1. The wordline underdrive circuit 1150_m may have a smallest resistance.

When the first wordline WL1 is selected, the first wordline WL1 may be set to a first wordline voltage VWL1 through the wordline underdrive circuit 1150_1. When the second wordline WL2 is selected, the second wordline WL2 may be set to a second wordline voltage VWL2 through the wordline underdrive circuit 1150_2. When the kth wordline WLk is selected, the kth wordline WLk may be set to a third wordline voltage VWL3 through the wordline underdrive circuit 1150_k. When the k+1th wordline WLk+1 is selected, the k+1th wordline WLk+1 may be set to a fourth wordline voltage VWL4 through the wordline underdrive circuit 1150_k+1. When the mth wordline WLm is selected, the mth wordline WLm may be set to a fifth wordline voltage VWL5 through the wordline underdrive circuit 1150_m.

The first wordline WL1 located farthest from the column decoder 1130 or the input/output circuit 1140 may be set to the first wordline voltage VWL1 that is a highest wordline voltage among the wordline voltages VWL1 to VWL5. The second wordline voltage VWL2 may be set lower than the first wordline voltage VWL1. The third wordline voltage VWL3 may be set lower than the second wordline voltage VWL2. The fourth wordline voltage VWL4 may be set lower than the third wordline voltage VWL3. The fifth wordline voltage VWL5 may be set lower than the fourth wordline voltage VWL4. The mth wordline WLm located closest to the column decoder 1130 or the input/output circuit 1140 may be set to the fifth wordline voltage VWL5 that is a lowest wordline voltage among the wordline voltages VWL1 to VWL5.

According to an example embodiment, the wordline underdrive circuits 1150_1 to 1150_m may have the same resistance for each group. For example, a first underdrive group may include at least one wordline underdrive circuit including the wordline underdrive circuit 1150_1. At least one wordline underdrive circuit included in the first underdrive group may have the greatest resistance. A second underdrive group may include at least one wordline underdrive circuit including the wordline underdrive circuit 1150_k. At least one wordline underdrive circuit included in the second underdrive group may have a smaller resistance than the first underdrive group. A third underdrive group may include at least one wordline underdrive circuit including the wordline underdrive circuit 1150_m. At least one wordline underdrive circuit included in the third underdrive group may have a smaller resistance than the second underdrive group.

The number of wordline underdrive circuits included in one underdrive group may be different from the number of the wordline underdrive circuits included in another underdrive group. For example, the first underdrive group may include the wordline underdrive circuit 1150_1 and the wordline underdrive circuit 1150_2, and the second underdrive group may include the wordline underdrive circuit 1150_k. In some example embodiments, the first underdrive group may include the greatest number of wordline underdrive circuits. In some example embodiments, the second underdrive group may include the greatest number of wordline underdrive circuits. In some example embodiments, the third underdrive group may include the greatest number of wordline underdrive circuits.

The first underdrive group, the second underdrive group and the third underdrive group are exemplary, and the wordline underdrive circuits 1150_1 to 1150_m may be divided into at least two or more underdrive groups. As an example, the wordline underdrive circuits 1150_1 to 1150_m may be divided into two underdrive groups. As another example, the wordline underdrive circuits 1150_1 to 1150_m may be divided into four or more underdrive groups.

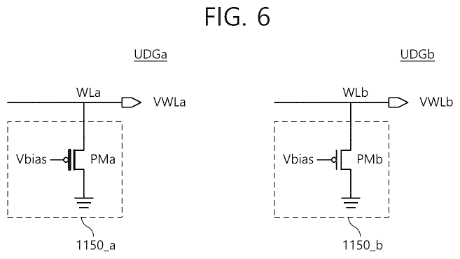

FIG. 6 is a diagram illustrating an example embodiment of the underdrive circuit of FIG. 5. Referring to FIGS. 5 and 6, a first underdrive circuit 1150_a may be included in a first underdrive group UDGa and may be connected to a first wordline WLa. A second underdrive circuit 1150_b may be included in a second underdrive group UDGb and may be connected to a second wordline WLb. The second wordline WLb may be located closer to the column decoder 1130 or the input/output circuit 1140 than the first wordline WLa.

The first underdrive circuit 1150_a may include a first transistor PMa driven by a bias voltage Vbias. The second underdrive circuit 1150_b may include a second transistor PMb driven by the bias voltage Vbias. In some example embodiments, the first transistor PMa may be configured to have a greater capacity than a capacity of the second transistor PMb. In some example embodiments, the first transistor PMa may be configured to have a greater capacitance than a capacitance of the second transistor PMb.

When driven with the same bias voltage Vbias, the first transistor PMa may have a greater resistance than the second transistor PMb. Accordingly, a first wordline voltage VWLa may be formed higher than a second wordline voltage VWLb.

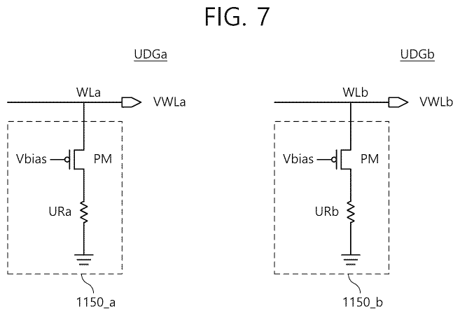

FIG. 7 is a diagram illustrating an example embodiment of the underdrive circuit of FIG. 5. Referring to FIGS. 5 and 7, a first underdrive circuit 1150_a may be included in a first underdrive group UDGa and connected to a first wordline WLa. A second underdrive circuit 1150_b may be included in a second underdrive group UDGb and connected to a second wordline WLb. The second wordline WLb may be located closer to the column decoder 1130 or the input/output circuit 1140 than the first wordline WLa.

The first underdrive circuit 1150_a may include a transistor PM driven by a bias voltage Vbias and a first underdrive resistor URa. The second underdrive circuit 1150_b may include the transistor PM driven by the bias voltage Vbias and a second underdrive resistor URb. The first underdrive resistor URa may be configured to have a greater resistance value than a resistance value of the second underdrive resistor URb.

When driven by the same bias voltage Vbias, the first underdrive resistor URa may have a greater voltage distribution effect than the second underdrive resistor URb. Accordingly, a first wordline voltage VWLa may be formed higher than a second wordline voltage VWLb.

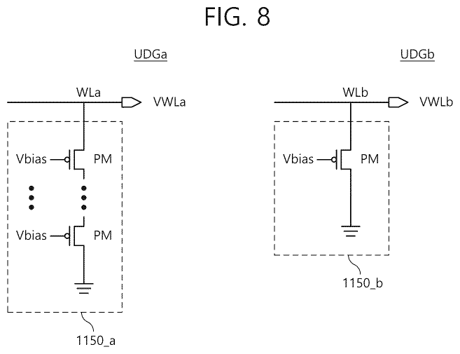

FIG. 8 is a diagram illustrating an example embodiment of the underdrive circuit of FIG. 5. Referring to FIGS. 5 and 8, a first underdrive circuit 1150_a may be included in a first underdrive group UDGa and may be connected to a first wordline WLa. A second underdrive circuit 1150_b may be included in a second underdrive group UDGb and may be connected to a second wordline WLb. The second wordline WLb may be located closer to the column decoder 1130 or the input/output circuit 1140 than the first wordline WLa.

The first underdrive circuit 1150_a may be driven by a bias voltage Vbias and may include a plurality of transistors PM connected in series. The second underdrive circuit 1150_b may include at least one transistor PM driven by the bias voltage Vbias. The first underdrive circuit 1150_a may have more transistors PM connected in series than the second underdrive circuit 1150_b. In an example embodiment, the second underdrive circuit 1150_b may include a plurality of transistors PM connected in series and driven by the bias voltage Vbias where the number of the plurality of transistors PM in the second underdrive circuit 1150_b is less than the number of the plurality of transistors PM in the first underdrive circuit 1150_a.

When driven by the same bias voltage Vbias, the first underdrive circuit 1150_a may have greater resistance than the second underdrive circuit 1150_b. Accordingly, a first wordline voltage VWLa may be formed higher than a second wordline voltage VWLb.

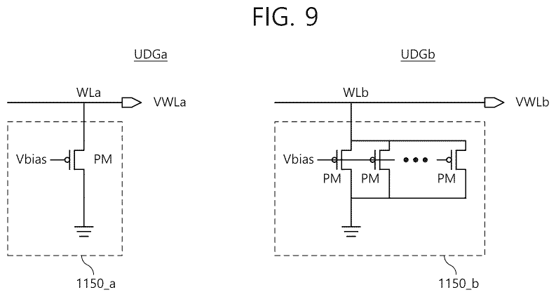

FIG. 9 is a diagram illustrating an example embodiment of the underdrive circuit of FIG. 5. Referring to FIGS. 5 and 9, a first underdrive circuit 1150_a may be included in a first underdrive group UDGa and may be connected to a first wordline WLa. A second underdrive circuit 1150_b may be included in a second underdrive group UDGb and may be connected to a second wordline WLb. The second wordline WLb may be located closer to the column decoder 1130 or the input/output circuit 1140 than the first wordline WLa.

The first underdrive circuit 1150_a may include at least one transistor PM driven by a bias voltage Vbias. The second underdrive circuit 1150_b may be driven by the bias voltage Vbias and may include a plurality of transistors PM connected in parallel. The second underdrive circuit 1150_b may have more transistors PM connected in parallel than the first underdrive circuit 1150_a. In an example embodiment, the first underdrive circuit 1150_a may include a plurality of transistors PM connected in parallel and driven by the bias voltage Vbias where the number of the plurality of transistors PM in the first underdrive circuit 1150_a is less than the number of the plurality of transistors PM in the second underdrive circuit 1150_b.

When driven with the same bias voltage Vbias, the first underdrive circuit 1150_a may have greater resistance than the second underdrive circuit 1150_b. Accordingly, a first wordline voltage VWLa may be formed higher than a second wordline voltage VWLb.

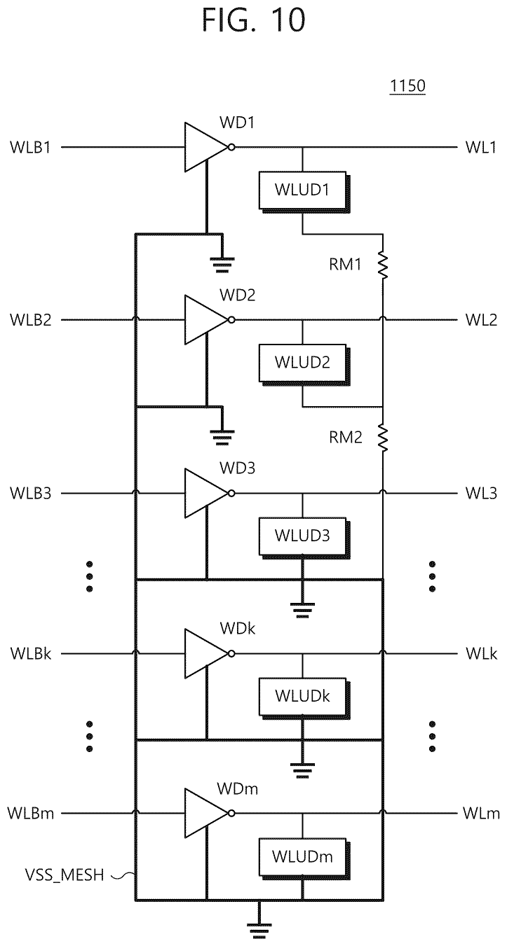

FIG. 10 is a diagram illustrating an example embodiment of the wordline voltage generator 1150 of FIG. 4. Referring to FIGS. 4 and 10, the wordline voltage generator 1150 may include an assist circuit to prevent a read disturbance. For example, the assist circuit may include wordline underdrive circuits WLUD1 to WLUDm. The wordline underdrive circuits WLUD1 to WLUDm may be respectively connected to a plurality of wordlines WL1 to WLm. The wordline underdrive circuits WLUD1 to WLUDm may have the same size of resistance.

Wordline drivers WD1 to WDm may be connected to a mesh-shaped ground terminal (hereinafter, mesh ground terminal VSS_MESH). A first portion of the wordline underdrive circuits WLUD1 to WLUDm may be directly connected to the mesh ground terminal VSS_MESH. A second portion of the wordline underdrive circuits WLUD1 to WLUDm may be connected to the mesh ground terminal VSS_MESH through a resistor.

For example, the third wordline underdrive circuit WLUD3 to the mth wordline underdrive circuit WLUDm may be directly connected to the mesh ground terminal VSS_MESH as illustrated in the example embodiment in FIG. 10. Accordingly, the third wordline WL3 to the mth wordline WLm may have the same wordline voltage level when selected.

The second wordline underdrive circuit WLUD2 may be connected to the mesh ground terminal VSS_MESH through a second metal resistor RM2 as illustrated in the example embodiment in FIG. 10. Accordingly, the second wordline WL2 may have a higher wordline voltage level than the third wordline WL3 when selected.

The first wordline underdrive circuit WLUD1 may be connected to the mesh ground terminal VSS_MESH through a first metal resistor RM1 and the second metal resistor RM2 connected in series as illustrated in the example embodiment in FIG. 10. Accordingly, the first wordline WL1 may have a higher wordline voltage level than the second wordline WL2 when selected.

Therefore, wordlines located within a specified distance from the column decoder 1130 or the input/output circuit 1140 may be set to the same wordline voltage level when selected. Wordlines located further away from the column decoder 1130 or the input/output circuit 1140 than the specified distance may be set to a higher wordline voltage level than the wordlines located within the specified distance when selected.

In some example embodiments, the first metal resistor RM1 and the second metal resistor RM2 may have the same resistance value. Accordingly, as a position of a wordline from the column decoder 1130 or the input/output circuit 1140 increases, the wordline voltage level may sequentially increase.

In some example embodiments, the first metal resistor RM1 and the second metal resistor RM2 may have different resistance values. Accordingly, as a position of a wordline from the column decoder 1130 or the input/output circuit 1140 increases, the wordline voltage level may increase in response to a difference in the resistance values of the first metal resistor RM1 and the second metal resistor RM2.

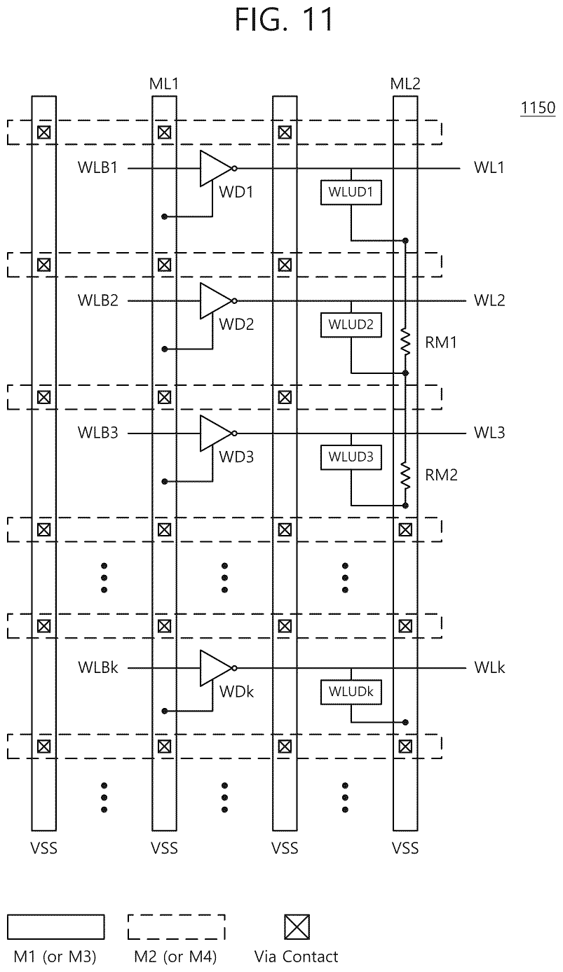

FIG. 11 is a diagram illustrating a layout of the wordline voltage generator 1150 of FIG. 10 according to an example embodiment. Referring to FIGS. 10 and 11, the wordline voltage generator 1150 may be connected to the mesh ground terminal VSS_MESH through a via contact. In FIG. 11, a solid line may be a M1 layer or a M3 layer. A dotted line may be a M2 layer or a M4 layer.

A memory device (for example, the memory device 1100 of FIG. 2) may connect different metal layers using via contacts in a semiconductor chip. A via contact process may be performed in following steps. First, an interlayer insulating layer may be formed. An insulating layer may be formed between metal layers to prevent electrical interference. Next, a via hole may be formed. A small hole may be made in the insulating layer to create a via hole. Next, a metal may be deposited. The via hole may be filled with metal to electrically connect the via contact. For example, tungsten W or copper Cu may be used as the metal. Next, a planarization CMP operation may be performed. After the metal is filled, the surface may be made flat and the next process may be prepared.

The wordline drivers WD1 to WDm may be connected to the mesh ground terminal VSS_MESH through a first metal line ML1. The third wordline underdrive circuit WLUD3 to the mth wordline underdrive circuit WLUDm may be connected to the mesh ground terminal VSS_MESH through a second metal line ML2.

As the process is refined, a long metal line may have a resistance component. A part of the second metal line ML2 may not be connected to the mesh ground terminal VSS_MESH by omitting the via contact. A part of the second metal line ML2 of a specified length which is not connected to the mesh ground terminal VSS_MESH may have a resistance component. Accordingly, the first metal resistor RM1 and the second metal resistor RM2 may be implemented through a part of the second metal line ML2.

The third wordline underdrive circuit WLUD3 to the mth wordline underdrive circuit WLUDm may be directly connected to the mesh ground terminal VSS_MESH. Accordingly, the third wordline WL3 to the mth wordline WLm may have the same wordline voltage level when selected.

The second wordline underdrive circuit WLUD2 may be connected to the mesh ground terminal VSS_MESH through the second metal resistor RM2. Accordingly, the second wordline WL2 may have a higher wordline voltage level than the third wordline WL3 when selected.

The first wordline underdrive circuit WLUD1 may be connected to the mesh ground terminal VSS_MESH through the first metal resistor RM1 and the second metal resistor RM2 connected in series. Accordingly, the first wordline WL1 may have a higher wordline voltage level than the second wordline WL2 when selected.

According to the present disclosure, it may be possible to prevent errors of the memory device in a power-efficient manner during a read or write operation.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a memory cell array including a plurality of memory cells;
a row decoder configured to select one of a plurality of wordlines connected to the plurality of memory cells based on an address received from a memory controller; and
a wordline voltage generator configured to provide a wordline voltage to a selected wordline,
wherein the wordline voltage generator comprises:
a plurality of wordline drivers that respectively correspond to the plurality of wordlines; and
a plurality of wordline underdrive circuits that respectively correspond to the plurality of wordlines and that lower wordline voltage levels that are output by the plurality of wordline drivers by different voltage levels based on the address.

2. The memory device of claim 1, further comprising:
an input/output circuit configured to input data to the memory cell array or output data from the memory cell array,
wherein the plurality of wordlines include a first wordline that is located farthest from the input/output circuit and a second wordline that is located between the first wordline and the input/output circuit, and
wherein the plurality of wordline underdrive circuits comprises:
a first underdrive circuit configured to lower a first wordline voltage level of the first wordline by a first voltage level when the first wordline is selected; and
a second underdrive circuit configured to lower a second wordline voltage level of the second wordline by a second voltage level that is greater than the first voltage level when the second wordline is selected.

3. The memory device of claim 2, wherein the first underdrive circuit includes a first transistor that has a first capacitance, that is connected between the first wordline and a ground terminal, and is configured to be driven by a bias voltage, and
wherein the second underdrive circuit includes a second transistor that has a second capacitance that is less than the first capacitance, that is connected between the second wordline and the ground terminal, and that is configured to be driven by the bias voltage.

4. The memory device of claim 2, wherein the first underdrive circuit includes a first transistor that is connected in series with a first resistor between the first wordline and a ground terminal and that is driven based on a bias voltage, and
wherein the second underdrive circuit includes a second transistor that is connected in series with a second resistor between the second wordline and the ground terminal and that is driven based on the bias voltage, the second resistor having a second resistance value that is less than a first resistance value of the first resistor.

5. The memory device of claim 2, wherein the first underdrive circuit includes a plurality of transistors connected in series between the first wordline and a ground terminal, and the first underdrive circuit is configured to be driven based on a bias voltage,
wherein the second underdrive circuit includes at least one transistor connected in series between the second wordline and the ground terminal, and the second underdrive circuit is configured to be driven based on the bias voltage, and
wherein a number of the plurality of transistors included in the first underdrive circuit is greater than a number of the at least one transistor included in the second underdrive circuit.

6. The memory device of claim 2, wherein the second underdrive circuit includes a plurality of transistors connected in parallel between the second wordline and a ground terminal, and the second underdrive circuit is configured to be driven based on a bias voltage,
wherein the first underdrive circuit includes at least one transistor connected in parallel between the first wordline and the ground terminal, and the first underdrive circuit is configured to be driven based on the bias voltage, and
wherein a number of the plurality of transistors included in the second underdrive circuit is greater than a number of the at least one transistor included in the first underdrive circuit.

7. The memory device of claim 1, wherein the plurality of wordline drivers are configured to be connected to a mesh ground terminal that is connected in a mesh form, and
a portion of the plurality of wordline underdrive circuits are configured to be connected to the mesh ground terminal.

8. The memory device of claim 7, wherein one of the plurality of wordline underdrive circuits is configured to be connected to the mesh ground terminal through a first resistor.

9. The memory device of claim 8, wherein another one of the plurality of wordline underdrive circuits is configured to be connected to the mesh ground terminal through the first resistor and a second resistor that are connected in series.

10. A memory device comprising:
a memory cell array including a first memory cell and a second memory cell;
a row decoder configured to select one of a first wordline connected to the first memory cell and a second wordline connected to the second memory cell based on an address received from a memory controller;
a first wordline driver configured to provide a wordline voltage to the first wordline when the first wordline is selected;
a second wordline driver configured to provide the wordline voltage to the second wordline when the second wordline is selected;
a first wordline underdrive circuit configured to reduce a voltage level of the first wordline by a first voltage level when the first wordline is selected; and
a second wordline underdrive circuit configured to reduce a voltage level of the second wordline by a second voltage level when the second wordline is selected, the second voltage level being greater than the first voltage level.

11. The memory device of claim 10, further comprising:
an input/output circuit configured to input data to the memory cell array or output data from the memory cell array,
wherein the first wordline is located farther from the input/output circuit than the second wordline.

12. The memory device of claim 10, wherein the second wordline underdrive circuit is directly connected to a mesh ground terminal that is connected in a mesh form, and
wherein the first wordline underdrive circuit is connected to the mesh ground terminal through a specified resistor.

13. The memory device of claim 12, wherein the specified resistor is configured to be implemented through a portion of a metal line constituting the mesh ground terminal.

14. The memory device of claim 10, wherein the first wordline underdrive circuit is configured to form a first resistance between the first wordline and a ground terminal, and
wherein the second wordline underdrive circuit is configured to form a second resistance between the second wordline and the ground terminal, the second resistance being less than the first resistance.

15. The memory device of claim 10, wherein the first wordline underdrive circuit includes a first transistor between the first wordline and a ground terminal, and the first transistor has a first capacitance and is configured to be driven by a bias voltage, and
wherein the second wordline underdrive circuit includes a second transistor between the second wordline and the ground terminal, and the second transistor has a second capacitance that is less than the first capacitance and is configured to be driven by the bias voltage.

16. A memory device comprising:
a memory cell array including a plurality of memory cells;
a row decoder configured to select one of a plurality of wordlines connected to the plurality of memory cells based on an address received from a memory controller; and
a wordline voltage generator configured to provide a wordline voltage level to a selected wordline that is different based on the address.

17. The memory device of claim 16, wherein the plurality of wordlines comprises a first wordline connected to a first memory cell and a second wordline connected to a second memory cell, and
wherein the wordline voltage generator comprises:
a first wordline driver configured to provide a wordline voltage to the first wordline when the first wordline is selected;
a second wordline driver configured to provide the wordline voltage to the second wordline when the second wordline is selected;
a first wordline underdrive circuit configured to reduce a voltage level of the wordline voltage of the first wordline by a first voltage level when the first wordline is selected; and
a second wordline underdrive circuit configured to reduce the voltage level of the wordline voltage of the second wordline by a second voltage level when the second wordline is selected, the second voltage level being greater than the first voltage level.

18. The memory device of claim 17, further comprising:
an input/output circuit configured to input data to the memory cell array or output data from the memory cell array, and
wherein the first wordline is located farther from the input/output circuit than the second wordline.

19. The memory device of claim 17, wherein the second wordline underdrive circuit is configured to be directly connected to a mesh ground terminal that is connected in a mesh form, and
wherein the first wordline underdrive circuit is configured to be connected to the mesh ground terminal through a specified resistor.

20. The memory device of claim 19, wherein the specified resistor is configured to be implemented through a portion of a metal line that constitutes the mesh ground terminal.
